(19) United States
(12) Patent Application Publication
(10) Pub. No.: US 2024/0102830 A1
(43) Pub. Date: Mar. 28, 2024

(54) BARRIER LAYERS FOR ANISOTROPIC MAGNETO-RESISTIVE SENSORS

(71) Applicant: Texas Instruments Incorporated, Dallas, TX (US)

(72) Inventors: Fuchao Wang, PLANO, TX (US); William French, SAN JOSE, CA (US); Ricky A. Jackson, RICHARDSON, TX (US); Erika Mazotti, SAN MARTIN, CA (US)

(21) Appl. No.: 18/147,396

(22) Filed: Dec. 28, 2022

Related U.S. Application Data
(60) Provisional application No. 63/377,285, filed on Sep. 27, 2022.

(51) Int. Cl. G01D 5/16; G01D 5/18; G01R 33/09

(52) U.S. Cl. CPC G01D 5/16; G01D 5/18; G01R 33/096

(57) ABSTRACT

Barrier layers for anisotropic magneto-resistive (AMR) sensors integrated with semiconductor circuits and methods of making the same are described. The AMR sensors includes a NiFe alloy layer disposed over a dielectric layer. The NiFe alloy layer is in contact with a conductive via coupled to the semiconductor circuits in a substrate underneath the AMR sensor. A barrier layer is formed on the dielectric layer to prevent Ni or Fe atoms from diffusing through the dielectric layer toward the semiconductor circuits. Further, a sacrificial layer is used to facilitate forming a planarized surface with ends of the conductive vias exposed without compromising the barrier layer.

### CROSS-REFERENCE TO RELATED APPLICATIONS

The present application for patent claims the benefit of U.S. Provisional Patent Application No. 63/377,285, entitled “Protecting Barrier Layer during CMP Process,” filed Sep. 27, 2022, which is hereby incorporated by reference in its entirety herein.

### TECHNICAL FIELD

The present disclosure generally relates to an integrated circuits (IC) and more particularly to ICs with integrated anisotropic magneto-resistive (AMR) sensors including barrier layers for the AMR sensors and methods for making the same.

### BACKGROUND

Contactless sensing based on integrated AMR sensors are used for rotation sensing technology. Such AMR sensors are formed by depositing an AMR film on a surface of ICs. The surface includes interconnect structures exposed such that the AMR sensors including the AMR film can be connected to underlying circuitry of the ICs to perform various functions associated with rotation sensing. Providing the surface having the interconnect structures exposed, however, may be challenging, for example, due to poor adhesion between conductive materials of the interconnect structures and the surface of the ICs.

### SUMMARY

The present disclosure describes barrier layers for AMR sensors and methods of making the same. This summary is not an extensive overview of the disclosure, and is neither intended to identify key or critical elements of the disclosure, nor to delineate the scope thereof. Rather, the primary purpose of the summary is to present some concepts of the disclosure in a simplified form as a prelude to a more detailed description that is presented later.

In some embodiments, a method includes forming a dielectric layer including a conductive pad, the dielectric layer disposed over a substrate including a semiconductor circuit coupled to the conductive pad; forming a barrier layer on the dielectric layer; forming a sacrificial layer on the barrier layer, the sacrificial layer having a surface facing away from the dielectric layer; forming an opening extending from the surface of the sacrificial layer to the conductive pad; forming a metal layer on the surface of the sacrificial layer, where the metal layer fills the opening; removing the metal layer and at least a portion of the sacrificial layer, where an upper surface of the metal layer in the opening is exposed as a result of removing the metal layer; and forming an anisotropic magneto-resistive (AMR) stack over the barrier layer, the AMR stack being in contact with the upper surface of the metal layer in the opening.

In some embodiments, a semiconductor device includes a substrate including a semiconductor circuit; a dielectric layer disposed over the substrate, the dielectric layer including a conductive pad coupled to the semiconductor circuit; a barrier layer disposed on the dielectric layer; a conductive via with a first end connected to the conductive pad, the conductive via extending from the conductive pad through the dielectric layer and the barrier layer; and an anisotropic magneto-resistive (AMR) stack disposed over the barrier layer, where the AMR stack is in contact with a second end of the conductive via opposite the first end.

In some embodiments, a semiconductor device includes a substrate including a semiconductor circuit; a protective overcoat layer disposed over the substrate, the protective overcoat layer including a conductive pad coupled to the semiconductor circuit; a silicon nitride layer disposed on the protective overcoat layer; a conductive via with a first end connected to the conductive pad, the conductive via extending from the conductive pad through the protective overcoat layer and the silicon nitride layer; and an anisotropic magneto-resistive (AMR) stack disposed over the silicon nitride layer, where the AMR stack is in contact with a second end of the conductive via opposite the first end.

These and other aspects of the present disclosure may be understood with reference to the following detailed description.

### BRIEF DESCRIPTION OF THE DRAWINGS

Various features are described with reference to the figures. The figures may or may not be drawn to scale and the elements of similar structures or functions are represented by like reference numerals throughout the figures. To facilitate understanding, identical reference numerals have been used, where possible, to designate the same or substantially similar elements that are common to the figures. Elements of one example may be beneficially incorporated in other examples. The figures are only intended to facilitate the description of the features, and are not intended as an exhaustive description of illustrated examples or as a limitation on the scope of the claims. Additionally, an illustrated example needs not have all the aspects or advantages shown. An aspect or an advantage described in conjunction with a particular example is not necessarily limited to that example and can be practiced in any other examples even if not so illustrated, or if not so explicitly described.

FIG. 1 is a schematic cross-sectional diagram of a semiconductor device in accordance with embodiments of the present disclosure;

FIG. 2 is a flowchart illustrating methods of making semiconductor devices in accordance with aspects of the present disclosure;

FIGS. 3A through 3G are cross-sectional schematic diagrams illustrating process steps of making semiconductor devices in accordance with embodiments of the present disclosure;

FIG. 4 is a schematic cross-sectional diagram of a semiconductor device in accordance with embodiments of the present disclosure; and

FIG. 5 is a schematic cross-sectional diagram of a semiconductor device in accordance with embodiments of the present disclosure.

### DETAILED DESCRIPTION

The present disclosure is described with reference to the attached figures. The components in the figures are not drawn to scale. Instead, emphasis is placed on clearly illustrating overall features and the principles of the present disclosure. Numerous specific details and relationships are set forth with reference to example embodiments of the figures to provide an understanding of the disclosure. It is to be understood that the figures and examples are not meant to limit the scope of the present disclosure to such example embodiments, and other embodiments are possible by way of interchanging or modifying at least some of the described or illustrated elements. Moreover, where elements of the present disclosure can be partially or fully implemented using known components, those portions of such components that facilitate an understanding of the present disclosure are described, and detailed descriptions of other portions of such components are omitted so as not to obscure the disclosure.

Various structures disclosed herein can be formed using semiconductor process techniques. Layers including a variety of materials can be formed over a substrate, for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps.

The semiconductor devices, integrated circuits (IC), or IC components described herein may be formed on a semiconductor substrate (or die) including various semiconductor materials, such as silicon, germanium, silicon-germanium alloy, gallium arsenide, gallium nitride, silicon carbide, or the like. In some cases, the substrate refers to a semiconductor wafer. The conductivity (or resistivity) of the substrate (or regions of the substrate) can be controlled by doping techniques using various chemical species (which may also be referred to as dopant atoms) including, but not limited to, boron, indium, arsenic, or phosphorus—e.g., for a silicon substrate. Doping may be performed during the initial formation or growth of the substrate (or an epitaxial layer grown on the substrate), by ion-implantation, or other suitable doping techniques.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in the semiconductor devices in view of the orientation shown in the figures. For example, “upper” or “uppermost” can refer to a feature positioned closer to the top of a page than other features. It is to be understood that the terms so used are interchangeable under appropriate circumstances such that the embodiments of the technology described herein are, for example, capable of operation in other orientations than those illustrated or otherwise described herein. The term “approximately,” as used herein, may refer to ±5% to ±10% variations of the recited values in some cases. In other cases, the term “approximately” may refer to ±10% to ±20% variations of the recited values.

The present disclosure describes barrier layers for AMR sensors integrated with semiconductor circuits and/or components and methods of making the same. In the process of manufacturing AMR sensors in accordance with the present disclosure, an AMR stack is formed over a dielectric layer—e.g., an oxide layer, which may be referred to as a protective overcoat (PO) layer. The dielectric layer includes one or more metal layers (e.g., multi-level metal (MLM) layers) and interconnect structures that are coupled to the semiconductor circuits and/or components located in a substrate (e.g., Si substrate) underneath the dielectric layer. The AMR sensors are devised to be coupled to the semiconductor circuits and/or components through the MLM layers and interconnect structures. Accordingly, electrically conductive structures (e.g., conductive vias) connected to the MLM layers and interconnect structures are formed through the dielectric layer (e.g., PO layer) such that ends of the conductive vias are exposed above the dielectric layer prior to forming an AMR stack of the AMR sensors. In some embodiments, a chemical-mechanical planarization (CMP) process is used to form a planarized surface having the ends of the conductive vias exposed.

The AMR stack in accordance with the present disclosure includes a layer of NiFe alloy and a layer of aluminum nitride (AlN) formed on the NiFe alloy layer. The layer of AlN may be referred to as a capping layer. When the NiFe alloy layer is disposed over the dielectric layer (e.g., an oxide layer), a barrier layer is needed to prevent certain constituent atoms of the AMR stack (e.g., Ni, Fe atoms) from diffusing through the dielectric layer toward the underlying semiconductor circuits and/or components. Absent the barrier layer, the Ni and/or Fe atoms are expected to diffuse to reach the semiconductor circuits and/or components, and to cause reliability issues. The barrier layer may include a silicon nitride (SiN) layer that is thick enough to block the atoms of the AMR stack from diffusing through the barrier layer.

In some embodiments, however, the barrier layer may not be too thick if the underlying semiconductor circuits and/or components include one or more components configured to alter data stored in there in response to receiving ultraviolet (UV) light. Such components may include an electrically programmable read only memory (EPROM) with a floating gate. The EPROM cells may release electrons stored in the floating gate when UV light are shone to the EPROM cells to “erase” data stored therein. Accordingly, the barrier layer (e.g., SiN layer) needs to have a thickness that facilitates transmitting (e.g., passing on) UV lights to the underlying semiconductor circuits and/or components.

Accordingly, it is desirable to control the thickness of the barrier layer to satisfy the requirements. Namely, the barrier layer needs not only to be thick enough to block diffusion from the AMR layer but also to be thin enough to allow UV light transmission through the barrier layer. Moreover, reducing variations in the thickness of the barrier layer is advantageous, for example to curtail variations in the semiconductor device characteristics. Providing such a barrier layer (e.g., SiN layer) with a tight thickness control, however, may be challenging because introducing the barrier layer complicates forming the conductive vias exposed at the surface of the barrier layer, prior to forming the AMR stack. For instance, poor adhesion between a conductive material (e.g., tungsten) of the conductive vias and the barrier layer (e.g., SiN layer) may render the CMP process hard to control. For example, in random locations of the substrate, the entire barrier layer can be removed during the CMP process. Additionally, chunks of the underlying dielectric layer may be removed in some cases.

As described in more detail herein, the present disclosure provides for a sacrificial layer that facilitates forming a planarized surface with ends of the conductive vias exposed without losing the control of the barrier layer. In some embodiments, the sacrificial layer includes a tetraethyl orthosilicate (TEOS) layer. The conductive material (e.g., tungsten) of the conductive vias is expected to have improved adhesion to the sacrificial layer (e.g., TEOS layer) when compared to the barrier layer (e.g., SiN layer). The improved adhesion facilitates generating the planarized surface with the ends of the conductive vias exposed to the AMR stack in a controlled manner. In some embodiments, the sacrificial layer may be removed during the CMP process. In other embodiments, at least a portion of the sacrificial layer may remain after the CMP process.

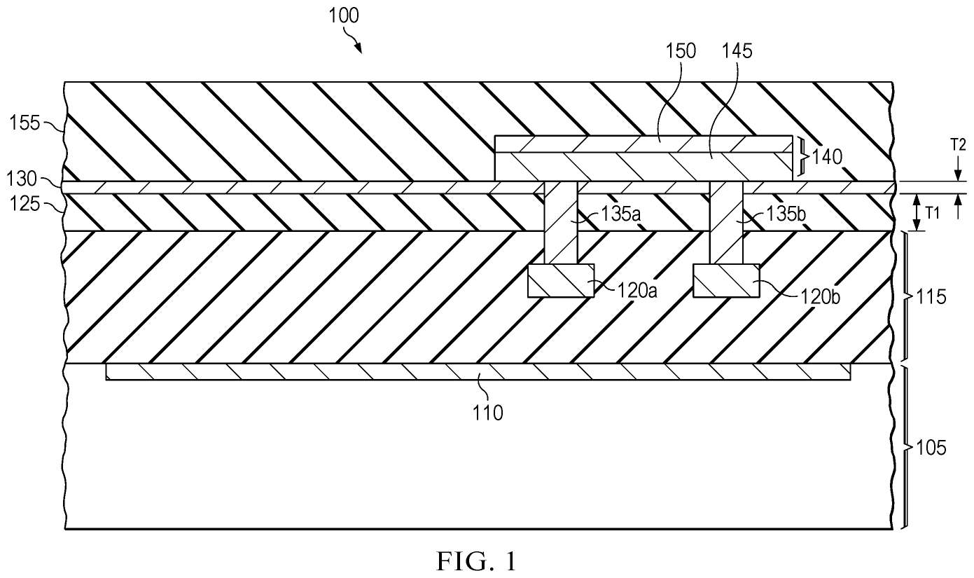

FIG. 1 is a schematic cross-sectional diagram of a semiconductor device 100 in accordance with embodiments of the present disclosure. The semiconductor device 100 includes a substrate 105, in which a semiconductor circuit 110 is formed. In some embodiments, the semiconductor circuit 110 performs various functions associated with rotation sensing in conjunction with an AMR sensor integrated over the substrate 105. In some embodiments, the semiconductor circuit 110 includes one or more components configured to alter data stored therein in response to receiving ultraviolet (UV) light. In some embodiments, the one or more components include an electrically programmable read only memory (EPROM) having a floating gate. The EPROM cells can be “erased” by shining UV light to the EPROM cells—e.g., releasing electrons stored in the floating gate in response to UV light shone to the EPROM cells.

The semiconductor device 100 includes a dielectric layer 115 disposed over the substrate 105. The dielectric layer 115 includes interconnect structures (e.g., conductive pads 120a and 120b) coupled to the semiconductor circuit 110 through one or more conductive layers (e.g., multi-level metal layers, omitted in FIG. 1) in the dielectric layer 115. The dielectric layer 115 may be referred to as a protective overcoat (PO) layer. In some embodiments, the dielectric layer 115 includes a silicon oxide layer (e.g., SiOx layer).

The semiconductor device 100 includes a barrier layer 125 disposed on the dielectric layer 115. In some embodiments, the barrier layer 125 includes a silicon nitride layer (e.g., SiN layer). As described herein, the barrier layer 125 blocks one or more constituent atoms (e.g., Ni or Fe atoms) of an AMR stack (e.g., AMR stack 140) from diffusing through the barrier layer 125. Additionally, the barrier layer 125 transmits UV light to the semiconductor circuit 110 (e.g., to the EPROM cells). In some embodiments, the barrier layer 125 has a thickness T1 as denoted in FIG. 1, which ranges from approximately 20 nanometers (nm) to approximately 200 nm. The thickness T1 of the barrier layer 125 may correspond to an initial thickness (e.g., as-deposited thickness) of the barrier layer 125. In some embodiments, the thickness T of the barrier layer 125 is less than the initial thickness.

The semiconductor device 100 includes a sacrificial layer 130 disposed on the barrier layer 125. In some embodiments, the sacrificial layer 130 includes a TEOS layer. As described herein, the sacrificial layer 130 facilitates forming a planarized surface having interconnect structures (e.g., conductive vias 135a and 135b) exposed prior to depositing the AMR stack 140. In some embodiments, the sacrificial layer 130 has a thickness T2 as denoted in FIG. 1, which may be less than approximately 50 nm. The thickness T2 of the sacrificial layer 130 may be less than its initial thickness (e.g., as-deposited thickness). In some embodiments, the sacrificial layer 130 is completely removed prior to depositing the AMR stack 140.

The semiconductor device 100 includes conductive vias 135 (e.g., conductive vias 135a and 135b). The conductive via 135 has a first end connected to the conductive pad 120 (e.g., conductive pad 120a or 120b) and extends from the conductive pad 120 through the dielectric layer 115 and the barrier layer 125. Moreover, the conductive via 135 of the semiconductor device 100 extends through the sacrificial layer 130 such that a second end (opposite the first end) of the conductive via 135 is in contact with the AMR stack 140.

The semiconductor device 100 includes the AMR stack 140 connected to the conductive vias 135. The AMR stack 140 includes a layer 145 of NiFe alloy (a NiFe alloy layer 145) and a layer 150 of aluminum nitride (an AlN layer 150) disposed on the NiFe alloy layer 145. As depicted in FIG. 1, the NiFe alloy layer 145 is in contact with the second end of the conductive vias 135. The semiconductor device 100 further includes a passivation layer 155 covering the AMR stack 140. In some embodiments, the passivation layer 155 includes a silicon oxynitride layer (e.g., SiON layer). The AMR stack 140 depicted in FIG. 1 may be regarded as a schematic rendition of an AMR sensor including the AMR stack 140. As such, although FIG. 1 shows the AMR stack 140 coupled to the semiconductor circuit 110 through two conductive vias 135, the AMR sensor may be coupled to the semiconductor circuit 110 through multitudes of conductive vias and the multi-level metal layers not explicitly shown in FIG. 1.

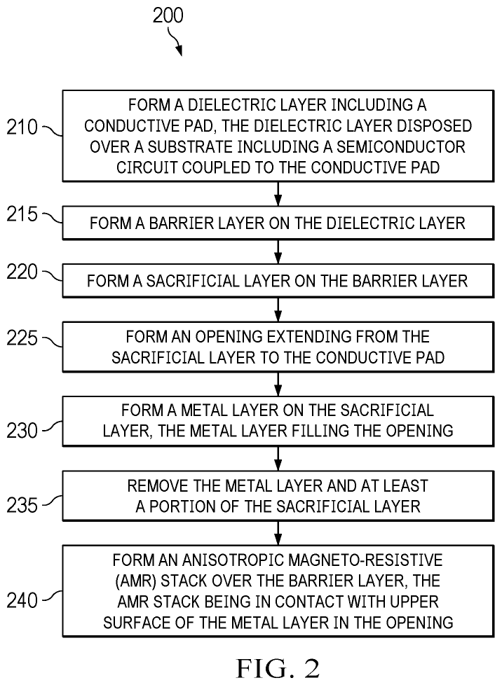

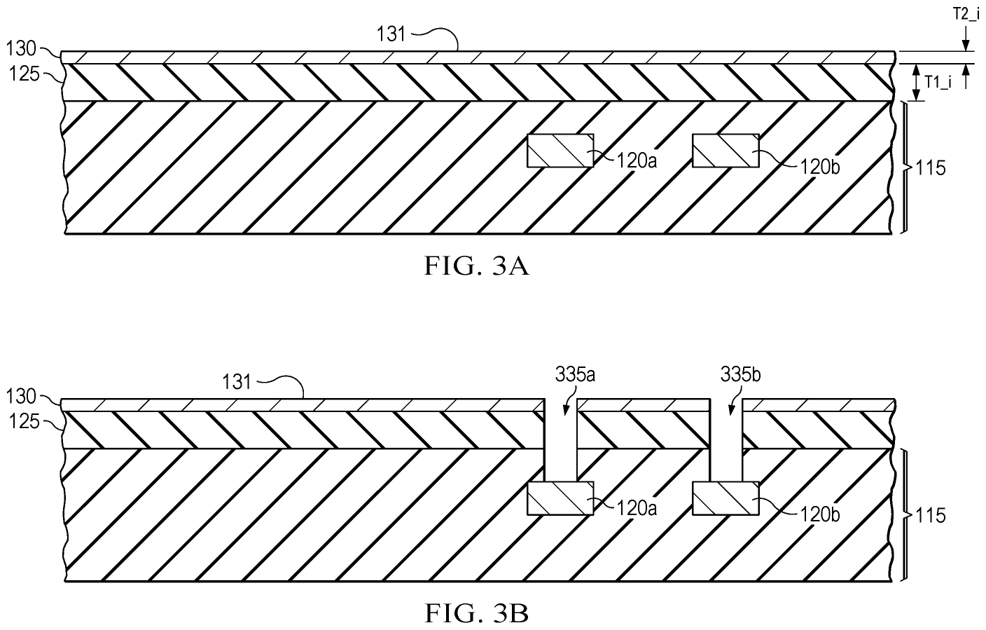

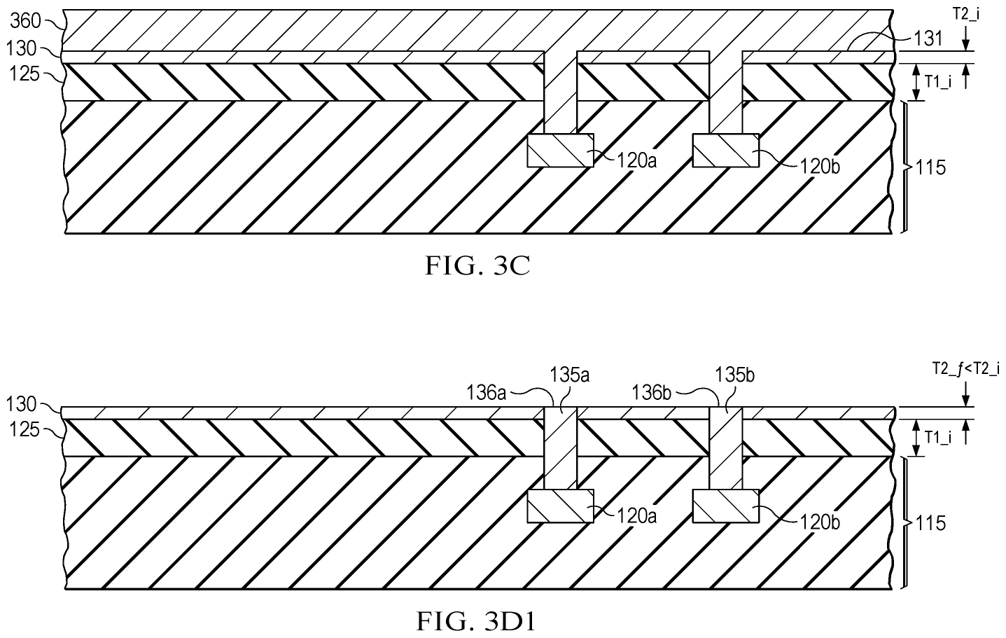

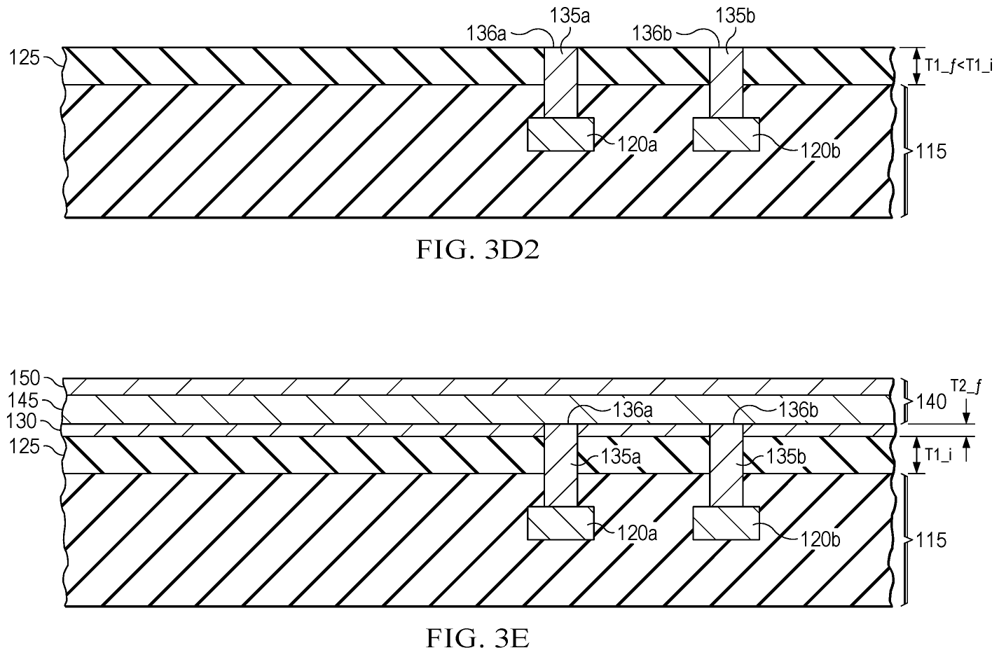

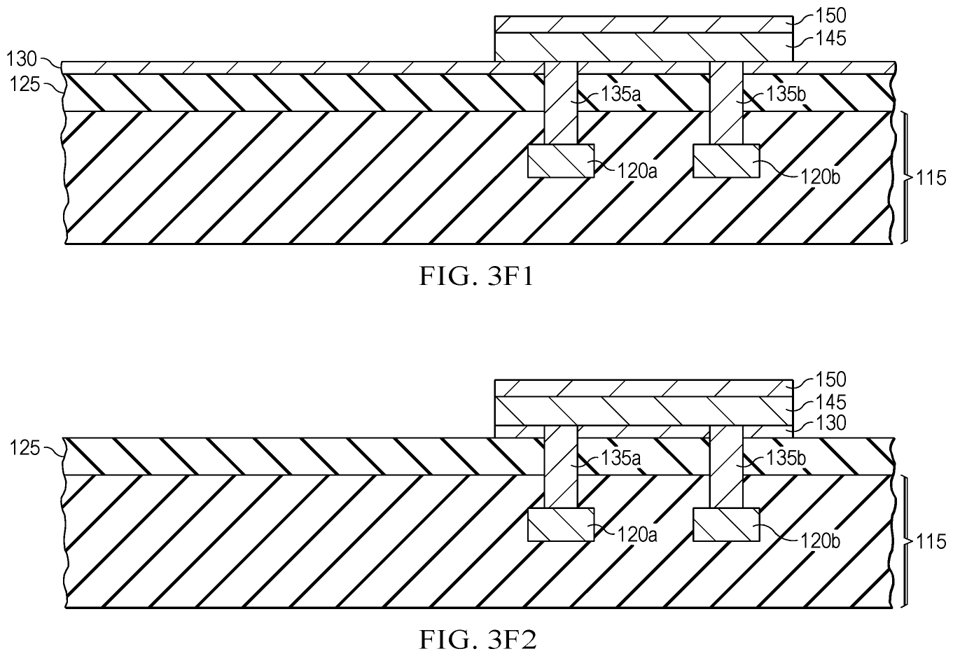

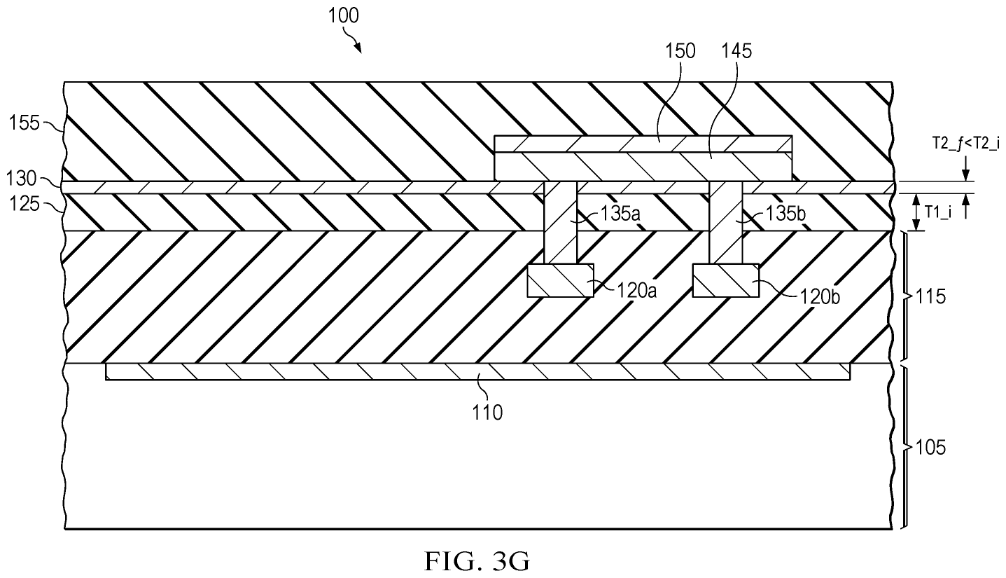

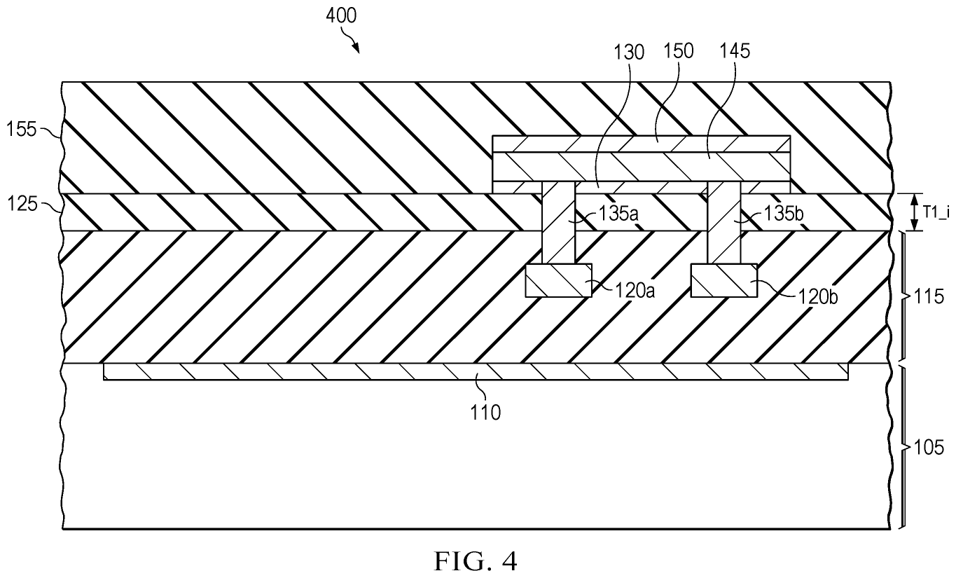

FIG. 2 is a flowchart 200 illustrating methods of making semiconductor devices (e.g., the semiconductor devices 100, 400, or 500) in accordance with aspects of the present disclosure. FIGS. 3A through 3G are cross-sectional schematic diagrams illustrating process steps of making the semiconductor devices in accordance with embodiments of the present disclosure. The substrate 105 and the semiconductor circuit 110 described with reference to FIG. 1 are omitted in FIGS. 3A through 3F2. Although FIGS. 3A through 3G illustrate a portion of the semiconductor device during the process steps, the process steps may be performed across an entire wafer (e.g., a substrate) including multitudes of the semiconductor devices—e.g., hundreds of the semiconductor devices concurrently formed across the wafer. Moreover, FIGS. 3A through 3G illustrate variations in the process steps to make semiconductor devices (e.g., semiconductor devices 400 or 500) in accordance with aspects of the present disclosure. FIG. 2 and FIGS. 3A through 3G are concurrently described in the following discussion.

The method includes forming a dielectric layer (e.g., dielectric layer 115) including a conductive pad (e.g., conductive pads 120a/b) as shown in FIG. 3A (box 210). The dielectric layer is disposed over a substrate (e.g., substrate 105) including a semiconductor circuit (e.g., the semiconductor circuit 110) that is coupled to the conductive pad. The method further includes forming a barrier layer (e.g., barrier layer 125) on the dielectric layer (box 215). The barrier layer has an initial thickness T1_i as denoted in FIG. 3A. In some embodiments, the barrier layer includes a silicon nitride (SiN) layer with a thickness ranging from approximately 20 nm to approximately 200 nm. The method further includes forming a sacrificial layer (e.g., sacrificial layer 130) on the barrier layer (box 220). The sacrificial layer has a surface (e.g., surface 131) facing away from the dielectric layer. The sacrificial layer has an initial thickness T2_i as denoted in FIG. 3A. In some embodiments, the sacrificial layer includes a tetraethyl orthosilicate (TEOS) layer with a thickness ranging from approximately 25 nm to approximately 100 nm.

The method includes forming an opening (e.g., openings 335a/b) extending from the surface of the sacrificial layer to the conductive pad as shown in FIG. 3B (box 225). In some embodiments, the opening are formed by performing an etch process (e.g., a plasma etch process) configured to etch through multiple dielectric layers in a single step—e.g., etching through the sacrificial layer, the barrier layer, and the dielectric layer above the conductive pad.

The method includes forming a metal layer (e.g., metal layer 360) on the surface of the sacrificial layer, and the metal layer fills the opening as shown in FIG. 3C (box 230). As described herein, the sacrificial layer provides improved adhesion for the metal layer—e.g., in comparison to the barrier layer.

The method includes removing the metal layer and at least a portion of the sacrificial layer (box 235). In some embodiments, a CMP process is utilized to remove the metal layer and to provide a planarized surface, on which an AMR stack is formed. FIG. 3D1 illustrates that the metal layer above the sacrificial layer and a portion of the sacrificial layer is removed (i.e., a portion of the sacrificial layer is retained or preserved). As a result of removing the metal layer, conductive vias (e.g., conductive vias 135a/b) are formed, and upper surfaces (e.g., upper surfaces 136a/b) of the conductive vias (i.e., the metal layer in the openings) are exposed. Accordingly, as shown in FIG. 3D1, the exposed upper surface of the conductive via is substantially coplanar with (or flush with) a surface of the sacrificial layer when the CMP process is complete. Moreover, as a portion of the sacrificial layer is removed (e.g., to ensure all the metal layer above the sacrificial layer is removed), the sacrificial layer may have a thickness T2_f that is less than its initial thickness T2_i. In other words, the retained portion of the sacrificial layer has the thickness T2_f.

In some embodiments, the CMP process stops after a predetermined duration of time such that the metal layer and a portion of the sacrificial layer is removed. Moreover, the CMP process may determine (or detect) a surface of the sacrificial layer is exposed at certain locations of the wafer (i.e., the metal layer is removed in those locations). The CMP process may be configured to continue for a fixed duration of time after determining that the surface of the sacrificial layer is exposed—e.g., to ensure removing the metal layer across the entire wafer. When the CMP process is complete, the sacrificial layer of T2_f remains on the barrier layer. As such, the barrier layer is intact during the CMP process, and maintains its initial thickness T1_i. Preserving the barrier layer intact during the CMP process may be advantageous for the semiconductor device 100 as the deposition process tends to provide superior control of the thickness (e.g., across a wafer).

Absent the sacrificial layer, the metal layer 360 may delaminate (e.g., from the barrier layer with relatively inferior adhesion to the barrier layer) during the CMP process, and the barrier layer may be exposed during the CMP process. If the barrier layer is exposed to the CMP process, the entire barrier layer may be removed in random locations of the wafer or only small portions of the barrier layer remain on the dielectric layer, which may be too thin to adequately block the undesirable diffusion of the Ni or Fe atoms from the AMR stack. Additionally, chunks of the underlying dielectric layer (e.g., PO layer) may be removed in some cases.

Alternative to leaving a portion of the sacrificial layer during the CMP process (as described with reference to FIG. 3D1), the entire sacrificial layer may be removed during the CMP process in some embodiments. Moreover, a portion of the barrier layer may be removed during the CMP process. FIG. 3D2 illustrates that the metal layer above the sacrificial layer, the sacrificial layer, and a portion of the barrier layer is removed after completing the CMP process. As a result of removing the metal layer, conductive vias (e.g., conductive vias 135a/b) are formed, and upper surfaces (e.g., upper surfaces 136a/b) of the conductive vias (i.e., the metal layer in the openings) are exposed. Accordingly, as shown in FIG. 3D2, the exposed upper surface of the conductive via is substantially coplanar with (or flush with) a surface of the barrier layer when the CMP process is complete. Moreover, as a portion of the barrier layer is removed, the barrier layer may have a thickness T1_f that is less than its initial thickness T1_i.

Moreover, the CMP process may determine (or detect) a surface of the barrier layer is exposed at certain locations of the wafer (i.e., the sacrificial layer is removed in those locations). The CMP process may be configured to continue for a fixed duration of time after determining that the surface of the barrier layer is exposed—e.g., to ensure removing the sacrificial layer across the entire wafer. When the CMP process is complete, the barrier layer of thickness T1_f remains on the dielectric layer as shown in FIG. 3D2.

The method includes forming an AMR stack (e.g., AMR stack 140) over the barrier layer as shown in FIG. 3E (box 240). The AMR stack is in contact with the upper surface of the conductive via (e.g., the metal layer in the opening). The AMR stack includes a layer of NiFe alloy (e.g., NiFe alloy layer 145) and a layer of AlN (e.g., AlN layer 150). As shown in FIG. 3E, the layer of NiFe alloy is in contact with the upper surface of the conductive via.

The method further includes patterning the AMR stack (e.g., to form an AMR sensor) coupled to the semiconductor circuit through the conductive pad. In some embodiments, an etch process (e.g., wet etch process, plasma etch process) may be used to pattern the AMR stack in conjunction with a photolithography process that protects the AMR stack of the AMR sensor. As shown in FIG. 3F1, the etch process may stop on the sacrificial layer in some embodiments. In other embodiments, the etch process may also remove the sacrificial layer and stop on the barrier layer as shown in FIG. 3F2.

The method further includes forming a passivation layer (e.g., passivation layer 155) covering the AMR sensor including the AMR stack as shown in FIG. 3G. In some embodiments, the passivation layer includes a silicon oxynitride (SiON) layer. FIG. 3G illustrates the semiconductor device 100 described with reference to FIG. 1 after forming the passivation layer.

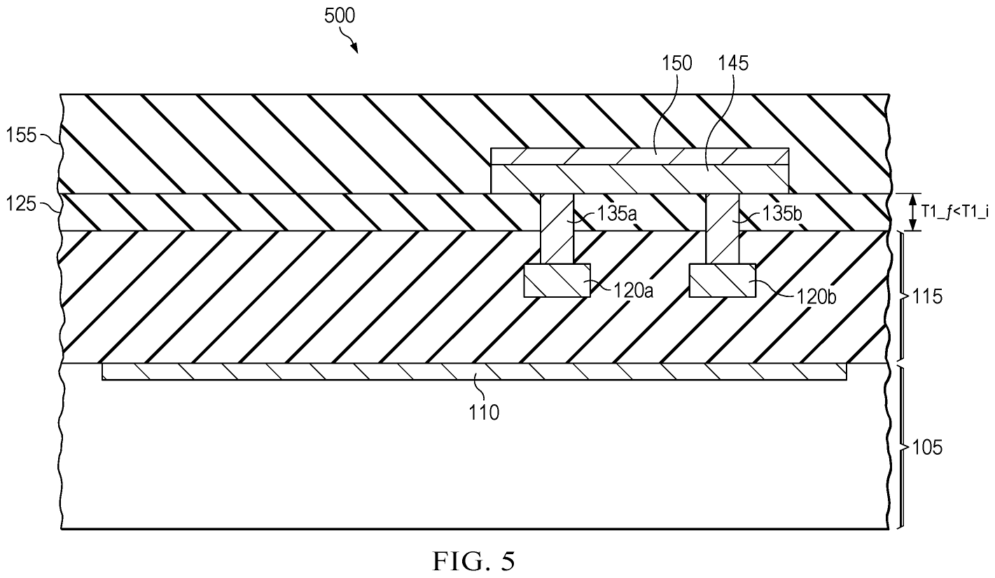

FIG. 4 is a cross-sectional schematic diagram of a semiconductor device 400 in accordance with embodiments of the present disclosure. The semiconductor device 400 includes aspects of the semiconductor device 100 described with reference to FIG. 1. In this regard, the semiconductor device 400 is a variation of the semiconductor device 100 in that the etch process used to pattern the AMR stack also removes a portion of the sacrificial layer uncovered by the AMR stack as described with reference to FIG. 3F2. As such, the sidewall surface of the AMR stack 140 is flush with (aligned with) the sidewall surface of the sacrificial layer 130.

FIG. 5 is a cross-sectional schematic diagram of a semiconductor device 500 in accordance with embodiments of the present disclosure. The semiconductor device 500 includes aspects of the semiconductor device 100 described with reference to FIG. 1. In this regard, the semiconductor device 500 is a variation of the semiconductor device 100 in that the CMP process used to remove the metal layer also removes the entire sacrificial layer as described with reference to FIG. 3D2. As such, the barrier layer 125 has a thickness T1_f that is less than its initial thickness T1_i.

While various embodiments of the present disclosure have been described above, it is to be understood that they have been presented by way of example and not limitation. Numerous changes to the disclosed embodiments can be made in accordance with the disclosure herein without departing from the spirit or scope of the present disclosure. In addition, while in the illustrated embodiments various features or components have been shown as having particular arrangements or configurations, other arrangements and configurations are possible. Moreover, aspects of the present technology described in the context of example embodiments may be combined or eliminated in other embodiments. Thus, the breadth and scope of the present disclosure is not limited by any of the above described embodiments.

What is claimed is:

1. A method, comprising:
forming a dielectric layer including a conductive pad, the dielectric layer disposed over a substrate including a semiconductor circuit coupled to the conductive pad;
forming a barrier layer on the dielectric layer;
forming a sacrificial layer on the barrier layer, the sacrificial layer having a surface facing away from the dielectric layer;
forming an opening extending from the surface of the sacrificial layer to the conductive pad;
forming a metal layer on the surface of the sacrificial layer, wherein the metal layer fills the opening;
removing the metal layer and at least a portion of the sacrificial layer, wherein an upper surface of the metal layer in the opening is exposed as a result of removing the metal layer; and
forming an anisotropic magneto-resistive (AMR) stack over the barrier layer, the AMR stack being in contact with the upper surface of the metal layer in the opening.

2. The method of claim 1, further comprising:
patterning the AMR stack to form an AMR sensor coupled to the semiconductor circuit through the conductive pad.

3. The method of claim 2, further comprising:
forming a passivation layer covering the AMR sensor.

4. The method of claim 1, wherein the AMR stack includes a layer of NiFe alloy, and wherein the layer of NiFe alloy is in contact with the upper surface of the metal layer in the opening.

5. The method of claim 4, wherein the barrier layer blocks Ni or Fe atoms of the AMR stack from diffusing through the barrier layer.

6. The method of claim 1, wherein the barrier layer blocks one or more constituent atoms of the AMR stack from diffusing through the barrier layer.

7. The method of claim 1, wherein the barrier layer transmits ultraviolet (UV) light to the semiconductor circuit.

8. The method of claim 1, wherein the semiconductor circuit includes one or more components configured to alter data stored therein in response to receiving ultraviolet (UV) light.

9. The method of claim 8, wherein the one or more components include an electrically programmable read only memory (EPROM) having a floating gate.

10. The method of claim 1, wherein the barrier layer includes a silicon nitride (SiN) layer with a thickness ranging from approximately 20 to approximately 200 nanometers (nm).

11. The method of claim 1, wherein the sacrificial layer includes a tetraethyl orthosilicate (TEOS) layer with a thickness ranging from approximately 25 to approximately 100 nanometers (nm).

12. The method of claim 1, wherein forming the opening includes etching the sacrificial layer, the barrier layer, and a portion of the dielectric layer above the conductive pad such that the conductive pad is exposed as a result of forming the opening.

13. The method of claim 1, wherein removing the metal layer and the at least the portion of the sacrificial layer includes performing a chemical-mechanical planarization (CMP) process to remove the metal layer from the surface of the sacrificial layer and the sacrificial layer in its entirety.

14. The method of claim 13, wherein the CMP process detects a surface of the barrier layer exposed as a result of removing the sacrificial layer.

15. The method of claim 13, wherein the CMP process removes a portion of the barrier layer.

16. The method of claim 13, wherein the AMR stack is in contact with the barrier layer.

17. The method of claim 1, wherein removing the metal layer and the at least the portion of the sacrificial layer includes performing a chemical-mechanical planarization (CMP) process to remove the metal layer from the surface of the sacrificial layer and to retain part of the sacrificial layer on the barrier layer.

18. The method of claim 17, wherein the CMP process stops after a predetermined duration of time.

19. The method of claim 17, wherein the AMR stack is in contact with the part of the sacrificial layer retained on the barrier layer.

20. A semiconductor device, comprising:
a substrate including a semiconductor circuit;
a dielectric layer disposed over the substrate, the dielectric layer including a conductive pad coupled to the semiconductor circuit;
a barrier layer disposed on the dielectric layer;
a conductive via with a first end connected to the conductive pad, the conductive via extending from the conductive pad through the dielectric layer and the barrier layer; and
an anisotropic magneto-resistive (AMR) stack disposed over the barrier layer, wherein the AMR stack is in contact with a second end of the conductive via opposite the first end.

21. The semiconductor device of claim 20, further comprising:
a passivation layer covering the AMR stack.

22. The semiconductor device of claim 20, wherein the AMR stack includes a layer of NiFe alloy, and wherein the layer of NiFe alloy is in contact with the second end of the conductive via.

23. The semiconductor device of claim 22, wherein the barrier layer blocks Ni or Fe atoms of the AMR stack from diffusing through the barrier layer.

24. The semiconductor device of claim 22, wherein the second end of the conductive via is coplanar with a surface of the barrier layer, and wherein the layer of NiFe alloy is disposed on the surface of the barrier layer.

25. The semiconductor device of claim 22, wherein the second end of the conductive via is coplanar with a surface of a sacrificial layer disposed on the barrier layer, and wherein the layer of NiFe alloy is disposed on the surface of the sacrificial layer.

26. The semiconductor device of claim 25, wherein the sacrificial layer includes a tetraethyl orthosilicate (TEOS) layer with a thickness ranging from approximately 5 to approximately 30 nanometers (nm).

27. The semiconductor device of claim 20, wherein the barrier layer blocks one or more constituent atoms of the AMR stack from diffusing through the barrier layer.

28. The semiconductor device of claim 20, wherein the semiconductor circuit includes one or more components configured to alter data stored therein in response to receiving ultraviolet (UV) light.

29. The semiconductor device of claim 28, wherein the one or more components include an electrically programmable read only memory (EPROM) having a floating gate.

30. The semiconductor device of claim 20, wherein the barrier layer transmits ultraviolet (UV) light to the semiconductor circuit.

31. The semiconductor device of claim 20, wherein the barrier layer includes a silicon nitride (SiN) layer with a thickness ranging from approximately 20 to approximately 100 nanometers (nm).

32. A semiconductor device, comprising:
a substrate including a semiconductor circuit;
a protective overcoat layer disposed over the substrate, the protective overcoat layer including a conductive pad coupled to the semiconductor circuit;
a silicon nitride layer disposed on the protective overcoat layer;
a conductive via with a first end connected to the conductive pad, the conductive via extending from the conductive pad through the protective overcoat layer and the silicon nitride layer; and
an anisotropic magneto-resistive (AMR) stack disposed over the silicon nitride layer, wherein the AMR stack is in contact with a second end of the conductive via opposite the first end.

33. The semiconductor device of claim 32, wherein the semiconductor circuit includes an electrically programmable read only memory (EPROM) having a floating gate, the EPROM configured to alter data stored therein in response to ultraviolet (UV) light.

34. The semiconductor device of claim 32, wherein the silicon nitride layer transmits ultraviolet (UV) light to the semiconductor circuit.

35. The semiconductor device of claim 32, wherein the silicon nitride layer has a thickness ranging from approximately 20 to approximately 100 nanometers (nm).

36. The semiconductor device of claim 32, wherein the AMR stack includes a layer of NiFe alloy, and wherein the layer of NiFe alloy is in contact with the second end of the conductive via.

37. The semiconductor device of claim 36, wherein the silicon nitride layer blocks Ni or Fe atoms of the AMR stack from diffusing through the silicon nitride layer.

38. The semiconductor device of claim 36, wherein the second end of the conductive via is coplanar with a surface of the silicon nitride layer, and wherein the layer of NiFe alloy is disposed on the surface of the silicon nitride layer.

39. The semiconductor device of claim 36, wherein the second end of the conductive via is coplanar with a surface of a tetraethyl orthosilicate (TEOS) layer disposed on the silicon nitride layer, and wherein the layer of NiFe alloy is disposed on the surface of the TEOS layer.

40. The semiconductor device of claim 39, wherein the TEOS layer has a thickness ranging from approximately 5 to approximately 30 nanometers (nm).

41. The semiconductor device of claim 32, further comprising:
a silicon oxynitride layer covering the AMR stack.
